(19) United States
(12) Patent Application Publication
(10) Pub. No.: US 2025/0037988 A1
(43) Pub. Date: Jan. 30, 2025

(54) SILICON OXIDE DEPOSITION METHOD

(71) Applicant: ASM IP Holding B.V., Almere (NL)

(72) Inventors: Varun Sharma, Helsinki (FI); Daniele Chiappe, Espoo (FI); Eva Tois, Espoo (FI); Viraj Madhiwala, Helsinki (FI); Marko Tuominen, Helsinki (FI); Charles Dezelah, Helsinki (FI); Michael Givens, Oud-Heverlee (BE); Tom Blomberg, Vantaa (FI)

(21) Appl. No.: 18/914,437

(22) Filed: Oct. 14, 2024

Related U.S. Application Data
(63) Continuation of application No. 17/472,981, filed on Sep. 13, 2021, now Pat. No. 12,148,609.
(60) Provisional application No. 63/079,239, filed on Sep. 16, 2020.

(51) Int. Cl. H01L 21/02

(52) U.S. Cl. CPC H01L 21/02164; H01L 21/02274; H01L 21/0228

(57) ABSTRACT

The current disclosure relates to methods of depositing silicon oxide on a substrate, methods of forming a semiconductor device and a method of forming a structure. The method comprises providing a substrate in a reaction chamber, providing a silicon precursor in the reaction chamber, the silicon precursor comprising a silicon atom connected to at least one oxygen atom, the at least one oxygen atom being connected to a carbon atom, and providing a reactant comprising hydrogen atoms in the reaction chamber to form silicon oxide on the substrate.

### CROSS-REFERENCE TO RELATED APPLICATIONS

This application is a continuation of, and claims priority to, U.S. patent application Ser. No. 17/472,981 filed Sep. 13, 2021 titled SILICON OXIDE DEPOSITION METHOD; which claims priority to U.S. Provisional Patent Application Ser. No. 63/079,239 filed Sep. 16, 2020 titled SILICON OXIDE DEPOSITION METHOD, the disclosure of which is hereby incorporated by reference in its entirety.

### FIELD

The present disclosure generally relates to the field of semiconductor device manufacturing. More particularly, the present disclosure relates to methods and apparatuses for thermally depositing a silicon oxide on a substrate.

### BACKGROUND

Silicon oxide (SiO₂) layers are used for a wide variety of applications in the manufacture of electronic devices, such as integrated circuits. They can be used as insulating layers and in the formation of spacers, for example. Silicon oxide layers are deposited on a surface of a substrate, and the deposition typically requires a separate oxygen reactant, such as ozone or oxygen plasma, or a relatively high deposition temperature when a thermal process is used. To allow the manufacture of complicated structures and devices, the deposition process should not harm the materials previously deposited on the substrate.

It may be desirable to deposit a silicon oxide layer only on certain areas of the substrate. This kind of selectivity may be achieved by first depositing a continuous layer on the substrate and subsequently patterning the layer using lithography and etching. These methods have price, efficiency and accuracy drawbacks, which is why selective deposition may offer an improved alternative in many situations. In selective processes, the target layer is deposited directly on the intended areas of the substrate, and no subsequent patterning is needed.

Thus, there is need in the art for a low-temperature, radical-free silicon oxide deposition process for growing layers selectively.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Embodiments of the present disclosure relate to methods of depositing silicon oxide on a substrate. In the method, a substrate is provided in a reaction chamber. Thereafter, a silicon precursor and a reactant comprising hydrogen atoms are provided in the reaction chamber to form silicon oxide on the substrate. The silicon precursor according to the current disclosure comprises a silicon atom connected to at least one oxygen atom, and the at least one oxygen atom is connected to a carbon atom. Said carbon may be, for example, a carbon in a carbonyl group.

Embodiments of the present disclosure also relate to methods of forming a structure, wherein silicon oxide is deposited by providing a substrate in a reaction chamber, providing a silicon precursor according to the current disclosure and a reactant comprising hydrogen atoms in the reaction chamber to form silicon oxide on the substrate.

Embodiments of the present disclosure further relate to methods of forming a semiconductor device, wherein the method comprises depositing silicon oxide by providing a substrate in a reaction chamber, providing a silicon precursor according to the current disclosure and a reactant comprising hydrogen atoms in the reaction chamber to form silicon oxide on the substrate.

Further embodiments of the present disclosure relate to a deposition assembly for depositing silicon oxide on a substrate. The deposition assembly comprises a reaction chamber constructed and arranged to hold the substrate and a precursor injector system constructed and arranged to provide a precursor and/or a reactant into the reaction chamber. The assembly further comprises a precursor vessel constructed and arranged to contain and evaporate a silicon precursor, wherein the silicon precursor comprises a silicon atom connected to at least one oxygen atom, and the at least one oxygen atom is connected to a carbon atom. The assembly is further constructed and arranged to provide the precursor via the precursor injector system to the reaction chamber to deposit the silicon oxide on the substrate.

Silicon oxide has many uses in semiconductor applications, and silicon oxide deposited according to the present disclosure may be used in in the manufacture of electronic devices, such as memory and/or logic circuits.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings:

FIGS. 1A and 1B illustrate embodiments of a method according to the current disclosure.

FIG. 2 is a schematic representation of a selective embodiment of the current disclosure.

FIG. 3 illustrates an embodiment of a selective method according to the current disclosure.

FIG. 4 is a schematic representation of an assembly according to the current disclosure.

Elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and apparatuses provided below is merely exemplary and is intended for purposes of illustration only. The following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims.

It will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. Unless otherwise noted, the exemplary embodiments or components thereof may be combined or may be applied separate from each other.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like.

Exemplary embodiments of the disclosure can be used to manufacture electronic devices, such as memory and/or logic circuits. More specifically, the embodiments of the current disclosure may be used to manufacture spacers, etch-stop layers, and any layers in which electrical insulating may be beneficial. The embodiments of the current disclosure may be used to produce a sacrificial layer and a patterning layer.

In one aspect, a method for depositing silicon oxide on a substrate is disclosed. In some embodiments, silicon oxide may form a layer. The term layer (or film) can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, the silicon oxide layer is continuous. In some embodiments, the silicon oxide layer is non-continuous.

The method of depositing silicon oxide according to the current disclosure comprises providing a substrate in a reaction chamber. In other words, a substrate is brought into space where the deposition conditions can be controlled. The substrate may comprise, consist essentially of, or consist of a dielectric, such as silicon oxide, SiN, SiOC, SiON, SiOCN, or any other material used in the art of manufacturing semiconductor devices. Examples of substrate materials include low k materials, metal-containing silicon oxide compounds, such as SiGeOx, metals and their alloys, including but not limited to copper, ruthenium, cobalt, niobium, tungsten, titanium, tantalum, iridium, gold, aluminum, iron, nickel, molybdenum, rhenium, manganese and vanadium. Further examples of substrate materials are metal oxides, such as copper oxide, ruthenium oxide, cobalt oxide, niobium oxide, tungsten oxide, titanium oxide, hafnium oxide, zirconium oxide, tantalum oxide, iridium oxide, gold oxide, zinc oxide, aluminum oxide, iron oxide, nickel oxide, molybdenum oxide, rhenium oxide, manganese oxide and vanadium oxide. The above metal oxides may be halogenated, for example, fluorinated. Further, in some embodiments, the substrate may comprise, consist essentially of, or consist of one or more metal nitride such as titanium nitride or tantalum nitride or aluminum nitride, metal carbide and/or metal boride. The substrate may comprise, consist essentially of, or consist of carbon-based material, such as amorphous carbon produced by spin-coating, PECVD or PEALD. The substrate may comprise photoresist material. In some embodiments, metal nitrides may be more amenable for silicon oxide deposition, wherein the reactant comprises oxygen. For example, the reactant may comprise water. In some embodiments, organic material-containing substrate surface may be more amenable for hydrogen and nitrogen-containing reactants. In such embodiments, the reactant may be a reactant not comprising oxygen, for example ammonia.

The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

As used herein, the term substrate may refer to any underlying material or materials that may be used to form, or upon which, a device, a circuit, material or a material layer may be formed. A substrate can include a bulk material, such as silicon (such as single-crystal silicon) and can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum or copper, or metallic materials, crystalline materials, epitaxial, heterocpitaxial, and/or single crystal materials. In some embodiments of the current disclosure, the substrate comprises silicon. The substrate may comprise other materials, as described above, in addition to silicon. The other materials may form layers.

The substrate can be patterned. Patterned substrates may include semiconductor device structures formed into or onto a surface of the substrate. For example, a patterned substrate may comprise partially or fully fabricated semiconductor device structures, such as, for example, transistors and/or memory elements. The patterned features can be formed by, for example, depositing layers of a material and etching a portion of the layer(s).

In the method according to the current disclosure, a silicon precursor is provided in the reaction chamber. A reactant comprising hydrogen atoms is also provided in the reaction chamber to form silicon oxide on the substrate. Silicon oxide is thus formed through the reaction of the silicon precursor and the reactant. The process of forming silicon oxide may take place through chemical vapor deposition (CVD) or atomic layer deposition (ALD), for example. In some embodiments, silicon oxide is deposited through a CVD process. In some embodiments, the current method is a cyclic deposition method. In some embodiments, silicon oxide is deposited through an ALD process. In some embodiments, the current method is an ALD method. In some embodiments, the current method is a CVD method.

In some embodiments, silicon oxide may be deposited by using plasma-enhanced CVD (PECVD). In some embodiments, silicon oxide may be deposited by using plasma-enhanced ALD (PEALD). Using a plasma-enhanced variant of a deposition process may allow decreasing the deposition temperature further. Alternatively or in addition, using a plasma-enhanced process may positively affect the quality of the deposited silicon oxide. The plasma may be hydrogen (H₂) plasma, nitrogen (N₂) plasma, argon (Ar) plasma, helium (He) plasma, neon (Ne) plasma, N₂/H₂ plasma, oxygen (O₂) plasma, NH₃ plasma, or a combination thereof. The plasma may be produced remotely (remote plasma) or in-situ (direct plasma). In some embodiments, the plasma is produced by gas-phase ionization of a gas with a radio frequency (RF) power. RF power may be between 100 W and 2,000 W.

CVD processes typically involve gas phase reactions between two or more reactants. The reactants can be provided simultaneously to the reaction chamber or substrate, or in partially or completely separated pulses (cyclic CVD). The substrate and/or reaction chamber can be heated to promote the reaction between the gaseous reactants. In some embodiments the reactant(s) and possible plasma are provided until a thin film having a desired thickness is deposited.

As used herein, ALD may refer to a vapor deposition process in which deposition cycles conduction in a reaction chamber. ALD is based on controlled, typically self-limiting surface reactions of the precursor chemicals. Gas-phase reactions are avoided by feeding the precursors alternately and sequentially into the reaction chamber. Generally, during each cycle, a first precursor (such as the silicon precursor) is chemisorbed to a deposition surface (e.g., a substrate surface that can include a previously deposited material from a previous ALD cycle or other material), forming about a monolayer or sub-monolayer of material that does not readily react with additional first precursor. Thereafter, in some cases, a second precursor, reactant or reaction gas (such as the hydrogen-containing reactant) may subsequently be introduced into the reaction chamber for use in converting the chemisorbed precursor to the desired material on the deposition surface. In some embodiments the process may start with the introduction of the second precursor, reactant or reaction gas (such as the hydrogen-containing reactant), and the first precursor (such as the silicon precursor) is introduced thereafter.

In ALD, vapor phase precursors and reactants may be separated from each other in the reaction chamber, for example, by removing excess reactants and/or reactant by-products from the reaction chamber between reactant pulses. This may be accomplished with an evacuation step and/or with an inactive gas pulse (purge). In some embodiments the substrate is contacted with a purge gas, such as an inert gas. For example, the substrate may be contacted with a purge gas between reactant pulses to remove excess reactant and reaction by-products. In some embodiments, the reaction chamber and/or substrate are purged of excess silicon precursor by an inert gas prior to providing the reactant in the reaction chamber. In some embodiments, the reaction chamber and/or substrate are purged of excess reactant by an inert gas prior to providing silicon precursor in the reaction chamber.

A purging gas pulse and/or vacuum generated by a pumping system may be used in removing excess precursor(s) and reaction byproducts from the reaction chamber and/or substrate surface. The purge gas can be any inert gas. A flowrate of a purge gas during purging the reaction chamber and/or substrate surface may range from about 500 sccm to about 4500 sccm or about 2000 sccm to about 4000 sccm. In some embodiments, the purge gas flow is set below 500 sccm. In some embodiments, the purge gas flow is about 300 sccm. In some embodiments, the purge gas flow is about 100 sccm. In some embodiments, the method comprises providing purge gas into the reaction chamber after providing a precursor and/or reactant in the reaction chamber. In some embodiments, the method comprises pumping down the reaction chamber after providing a precursor and/or reactant in the reaction chamber. Carrier gas may have similar flowrates as the purge gas. In some embodiments, the flowrates of the carrier gas and the purge gas are the same. In some embodiments, the flowrate of the purge gas is higher than the flowrate of the carrier gas. In some embodiments, the flowrate of the carrier gas is higher than the flowrate of the purge gas.

In some embodiments, the method comprises supplying inert gas to the reaction chamber. An inert gas may be used to provide a protective atmosphere for the substrate before and after depositing silicon oxide on the substrate. An inert gas may be used to purge the reaction chamber of precursor(s) and/or reaction by-products. An inert gas can be used to regulate the flow of precursor(s). Thus, the precursor concentration and residence time in the reaction chamber can be adjusted by using an inert gas. Such a gas may be called a carrier gas. In some embodiments, the method comprises supplying carrier gas in the reaction chamber. The term inert gas (including a carrier gas and a purge gas) can refer to a gas that does not take part in a chemical reaction and/or does not become a part of the deposited material to an appreciable extent. Exemplary inert gases include helium (He), argon (Ar), nitrogen (N₂) and hydrogen (H₂) and any combination thereof.

In some embodiments, the deposition of silicon oxide is performed at a pressure of less than about 0.001 Torr, less than 0.01 Torr, less than 0.1 Torr, less than 10 Torr or less than 50 Torr. In some embodiments, the pressure of the reaction chamber during at least a part of the method according to the current disclosure is less than about 0.001 Torr, less than 0.01 Torr, less than 0.1 Torr, less than 10 Torr or less than 50 Torr.

In some embodiments each reaction is self-limiting and monolayer by monolayer growth is achieved. These may be referred to as “true ALD” reactions. In some such embodiments the silicon precursor may adsorb on the substrate surface in a self-limiting manner. The reactant will react in turn with the adsorbed silicon precursor to form up to a monolayer of silicon oxide on the substrate.

Further, the term atomic layer deposition, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es).

In some embodiments the deposition process for a silicon oxide has one or more phases which are not self-limiting. For example, in some embodiments at least one of the silicon precursor and the reactant is at least partially decomposed on the substrate surface. Thus, in some embodiments the process may operate in a process condition regime close to CVD conditions, or in some cases fully in CVD conditions.

In some embodiments, silicon oxide deposition according to the current disclosure may be conformal. For example, silicon oxide deposited using an ALD-type reaction may form conformal layers.

In some embodiments, the method according to the current disclosure is a thermal deposition method. In thermal deposition, the chemical reactions are promoted by increased temperature relevant to ambient temperature. Generally, temperature increase provides the energy needed for the formation of silicon oxide in the absence of other external energy sources, such as plasma, radicals, or other forms of radiation. In some embodiments, the method according to the current disclosure is a plasma-enhanced deposition method, for example PEALD or PECVD.

The silicon precursor according to the current disclosure comprises a silicon atom connected to at least one oxygen atom, the at least one oxygen atom being connected to a carbon atom. In some embodiments, the silicon atom is connected to one oxygen atom, and the oxygen atom is connected to a carbon atom.

In some embodiments, the silicon atom in the silicon precursor is connected to a plurality of oxygen atoms. In other words, the silicon atom may be connected to two, three or four oxygen atoms. In embodiments where the silicon atom is connected to two oxygen atoms, one or both of the two oxygen atoms may be connected to a carbon atom. In embodiments where the silicon atom is connected to three oxygen atoms, one, two or three of the three oxygen atoms may be connected to a carbon atom. In embodiments where the silicon atom is connected to four oxygen atoms, one, two, three or four of the four oxygen atoms may be connected to a carbon atom. Thus, in some embodiments, the silicon atom is connected to at least three oxygen atoms, one, two or three of the oxygen atoms being further connected to a carbon atom.

In some embodiments, at least one of said carbon atoms in the silicon precursor is connected to a second oxygen atom. The second oxygen atom may be connected to said carbon atom through a double bond. Thus, the oxygen atom connected to the silicon atom may be connected to a carbonyl carbon atom. In other words, the carbon atom is connected to two oxygen atoms, one of them being connected to a silicon atom, and the other forming a carbonyl group with the carbon atom. In some embodiments, the silicon atom is connected to more than one oxygen atom, one, two, three or four of the oxygen atoms being further connected to a carbonyl carbon atom.

In some embodiments of the method according to the current disclosure, each said carbon atom in the silicon precursor (i.e., a carbon atom connected to a silicon atom through an oxygen atom) belongs to an independently selected unsubstituted, substituted and/or functionalized C1-C5 hydrocarbon. Thus, there may be one, two, three or four hydrocarbon groups in the silicon precursor.

SiRₐ(OOCR′)₄₋ₐ, Formula I

In some embodiments, the silicon precursor comprises a compound according to Formula I, wherein, each R and R′ are independently selected from hydrogen or unsubstituted, substituted, saturated, unsaturated and/or functionalized hydrocarbons, and 4>a≥0. Each R and R′ may be a linear hydrocarbon, a branched hydrocarbon, or a cyclic hydrocarbon or an aromatic hydrocarbon. The hydrocarbon may be a C1 to C10 hydrocarbon, such as C2, C3, C4, C5, C6, C7, C8 or C9 hydrocarbon. By way of example, each R and R′ may independently comprise a methyl, ethyl, propyl, butyl, pentyl, hexyl, heptyl and octyl group, including any of their isomers, such as n-, iso-, sec- and tert-isomers. An alkyl group may be linear, branched or cyclic, and may comprise any structural isomer of the alkyl group. An alkyl group may be substituted. A substituent of an alkyl group may be a single atom, such as a halogen, or a functional group, such as a hydroxyl group. In some embodiments, R may be a halogen. In some embodiments, R may be Cl, Br, I or F. In some embodiments, R and/or R′ may comprise a halogen. If there are more than one halogens in the silicon precursor, the halogen atom may be same or different.

Exemplary embodiments of the silicon precursor according to formula I may be, for example, molecules schematically represented by structures (1) to (4). As explained above, in the structures, each R and R′ may be independently selected from hydrogen or unsubstituted, substituted, saturated, unsaturated and/or functionalized hydrocarbons.

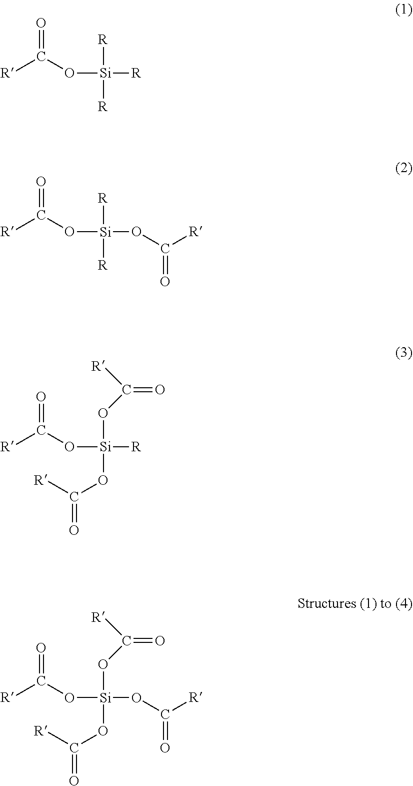

Examples of the silicon precursor are silicon tetraacetate (triacetyloxysilyl acetate), triacetoxy vinyl silane, silicontetrapropionate, triacetoxysilane, triacetoxy(methyl)silane, triacetoxy(methoxy) silane, diacetoxydimethylsilane. Further examples of silicon precursors are silicon(vinyl)tripropionate, silicon(vinyl)triacetate, SiCl(OAc)₃, SiCl₂(OAc)₂ and SiCl₃(OAc).

The reactant according to the current disclosure comprises hydrogen atoms. This means that there are at least two hydrogen atoms in the reactant molecule. In some embodiments, the reactant comprises at least one further atom, and this further atom is other than hydrogen. The further atom may be, for example nitrogen. The further atom may be oxygen. In some embodiments, the further atom is other than oxygen. In some embodiments, the reactant comprises hydrogen and nitrogen. In some embodiments, the reactant comprises hydrogen and oxygen.

In some embodiments, the reactant comprises ammonia (NH₃). In some embodiments, the reactant comprises ammonia mixed with an inert gas. In some embodiments, the reactant comprises ammonia nitrogen (NH₃—N₂) or ammonia-hydrogen (NH₃—H₂) mixture. In some embodiments, the reactant comprises either primary or secondary amines, for example dimethylamine, methylamine or ethanamine. In some embodiments, the reactant is a diamine, for example, ethane diamine or hexane diamine. In some embodiments, the reactant may comprise a mixture of at least two compounds.

In some embodiments, the reactant may comprise water (H₂O). In some embodiments, the reactant may comprise hydrogen peroxide (H₂O₂). In some embodiments, the reactant comprises an amine. The amine may be a primary amine, a secondary amine or a tertiary amine. In embodiments where the reactant comprises oxygen, the reactant may comprise an alcohol. The reactant may comprise formic acid (HCOOH). The reactant may consist essentially of, or consist of one compound.

In some embodiments, the reactant is selected from hydrazine (N₂H₄) or methyl-substituted hydrazines such as N,N-dimethyl hydrazine or N,N′-dimethyl hydrazine.

The silicon oxide may be formed at a temperature from about 65° C. to about 500° C. For example, silicon oxide may be formed at a temperature from about 100° C. to about 450° C., or at a temperature from about 150° C. to about 400° C. In some embodiments of the current disclosure, silicon oxide may be formed at a temperature from about 200° C. to about 400° C., or at a temperature from about 300° C. to about 350° C. For example, silicon oxide may be formed at a temperature of 75° C., or 125° C., or 175° C., or 225° C., 275° C. or 325° C. or 375° C.

Silicon oxide deposited according to the current disclosure may form a layer or a part of a layer. Silicon oxide, or silicon oxide-containing layer according to the current disclosure may comprises at least 50% silicon oxide or at least 70% silicon oxide, or at least 85% silicon oxide. Silicon oxide or silicon oxide-containing layer may comprise at least 90% silicon oxide, or at least 95% silicon oxide, or at least 98% silicon oxide. In some embodiments, the silicon oxide or silicon oxide-containing layer according to the current disclosure may comprise at least 99.5% silicon oxide. In some embodiments, the silicon oxide-containing layer may consist essentially of, or consist of silicon oxide.

In some embodiments, silicon oxide deposited according to the current disclosure, or a silicon oxide-containing layer may comprise less than 5 at-% carbon or less than 2 at-% carbon or less than 1 at-% carbon. If the reactant comprises nitrogen, some nitrogen may be incorporated into silicon oxide or silicon oxide-containing layer. In some embodiments, the silicon oxide or silicon oxide-containing layer may comprise less than 8 at-% nitrogen or less than 5 at-% nitrogen or less than 2 at-% nitrogen.

In some embodiments, silicon oxide deposited according to the method of the present disclosure may have wet etch rate similar to or same as that of thermal oxide. In some embodiments, silicon oxide deposited according to the method of the present disclosure may have wet etch rate twice or five times that of thermal oxide. In some embodiments, silicon oxide deposited according to the method of the present disclosure may have wet etch rate more than five times or more than ten times or more than 30 times that of thermal oxide. In some embodiments, silicon oxide deposited according to the method of the present disclosure may have wet etch rate less than 50 times that of thermal oxide. In some embodiments, silicon oxide deposited according to the method of the present disclosure may have wet etch rate in the range of 10-80 nm/min in 0.5% (v./v.) HF solution.

In some embodiments, silicon oxide deposited according to the method of the present disclosure may have dielectric constant of about 4, or less than about 5 or less than about 6. In some embodiments, silicon oxide deposited according to the method of the present disclosure may have dielectric constant of about 7. In some embodiments, the electrical breakdown of the silicon oxide may be in the range from about 8 to about 15 MV×cm⁻¹. In some embodiments the thermal conductivity of silicon oxide deposited according to the method of the present disclosure is similar to that of thermal oxide. In some embodiments, silicon oxide has thermal conductivity in the range of 0.2 to 2 Watt×meter⁻¹Kelvin⁻¹.

The method according to the current invention may be selective. Selective deposition may provide advantages in different applications. Selective deposition may be used in applications in several areas, for example, in the production of fully aligned vias, dielectric on dielectric deposition in the back-end-of-the-line, gate stack and isolating conducting lines. In some embodiments, the reactant used to selectively deposit silicon oxide does not contain oxygen. In some embodiments, the reactant used to selectively deposit silicon oxide comprises nitrogen. In some embodiments, the reactant used to selectively deposit silicon oxide comprises, consist essentially of, or consist of two or more of the elements oxygen, nitrogen and hydrogen. In some embodiments, the reactant used to selectively deposit silicon oxide comprises, consist essentially of, or consist of oxygen and nitrogen. In some embodiments, the reactant used to selectively deposit silicon oxide comprises, consist essentially of, or consist of hydrogen and nitrogen. In some embodiments, the reactant used to selectively deposit silicon oxide comprises, consist essentially of, or consist of ammonia, amine or hydrazine or an oxygen-containing reactant such as water, ozone or oxygen.

In some embodiments of the current disclosure, the substrate comprises a surface. The surface may comprise a first portion comprising a first material and a second portion comprising a second material. In some embodiments, the first portion comprises 20 at-% or more of the first material, or the first portion comprises 30 at-% or more of the first material, or the first portion comprises 50 at-% or more of the first material, or the first portion comprises 70 at-% or more of the first material, or the first portion comprises 85 at-% or more of the first material. The first portion may comprise 90 at-% or more of the first material, or 95 at-% or more of the first material. In some embodiments, the first portion may consist essentially of, or consist of first material. Correspondingly, in some embodiments, the second portion comprises 20 at-% or more of the second material, or the second portion comprises 30 at-% or more of the second material, or the second portion comprises 50 at-% or more of the second material, or the second portion comprises 70 at-% or more of the second material, or the second portion comprises 85 at-% or more of the second material. The second portion may comprise 90 at-% or more of the second material, or 95 at-% or more of the second material. In some embodiments, the second portion may consist essentially of or consist of second material.

The first portion and the second portion may be arranged as any suitable pattern. For example, the first portion and the second portion can be alternating lines or one portion can surround the other portion in a plan or in a 3-D view. The first and section portions can be coplanar, the first portion may be raised relative to the second portion, or the second portion can be raised relative to the first portion. The first and second portions may be formed using one or more reaction chambers. The patterned structure can be provided on any suitable substrate.

The first or second material may be selectively deposited on the first portion and/or second portion. The first and/or second material may be treated after they have been deposited (post-treatment).

The first material may comprise a dielectric. The dielectric may comprise silicon oxide (SiO₂), silicon nitride (SiN), silicon oxycarbide (SiOC), silicon oxynitride (SiON), silicon oxycarbonitirde (SiOCN) or low-k material such as SiOC or SiOCH or SiOH or carbon-based layer. In some embodiments, the dielectric consists essentially of, or consists of silicon oxide, silicon nitride, silicon oxycarbide (SiOC), silicon oxycarbonitirde (SiOCN) or low-k material. In some embodiments, the first material is silicon carbide. The first material may comprise, consist essentially of, or consist of metal-containing silicon oxide compounds or metal silicates, including, but not limited to SiGeOx, GeOx, AlSiOx, HfSiOx, LaSiOx, LaHfSiOx etc.

The first material may comprise, consist essentially of, or consist of a metal nitride, including but not limited to titanium nitride, tantalum nitride, aluminum nitride, titanium aluminum nitride, gallium nitride and nitride alloys containing indium, or aluminum, or gallium. The first material may comprise, consist essentially of, or consist of a metal carbide, including but not limited to titanium carbide, tungsten carbide, tantalum carbide and niobium carbide. The first material may comprise, consist essentially of, or consist of a metal boride, including but not limited to niobium boride, boron doped silicon, titanium boride, vanadium boride, lanthanum boride and cobalt boride.

The first material may comprise a metal or an alloy of metals, including but not limited to copper, ruthenium, cobalt, niobium, tungsten, titanium, tantalum, iridium, gold, aluminum, iron, nickel, molybdenum, rhenium, manganese and vanadium. Further, the first material may comprise a metal oxide, such as copper oxide, ruthenium oxide, cobalt oxide, niobium oxide, tungsten oxide, titanium oxide, hafnium oxide, zirconium oxide, tantalum oxide, iridium oxide, gold oxide, zinc oxide, aluminum oxide, iron oxide, nickel oxide, molybdenum oxide, rhenium oxide, manganese oxide and vanadium oxide.

The second material may comprise an organic material. For example, the organic material may be an organic polymer. In some embodiments, the organic material consists essentially of, or consists of carbon and hydrogen, whereas in some embodiments the organic material contains substantially only carbon, oxygen and hydrogen. In some embodiments, the organic material consists essentially of, or consists of carbon, nitrogen and hydrogen, and in yet further embodiments, the organic material consist essentially of, or consist of carbon, oxygen, nitrogen and hydrogen. In some embodiments, the organic material consist essentially of, or consist of carbon, nitrogen, sulfur and hydrogen, or of carbon, oxygen, sulfur and hydrogen, whereas in some embodiments, the organic material consist essentially of, or consist of carbon, oxygen, nitrogen, sulfur and hydrogen.

In some embodiments, the second material may comprise one or more SAM (self-aligned monolayer). The one or more SAM may be gas-phase SAM. The one or more SAM may be a liquid-phase SAM.

In some embodiments, silicon oxide is deposited selectively on dielectric material versus metal or metal alloy or metal oxide with organic passivation. In some embodiments, silicon oxide is deposited selectively on oxygen-containing silicon layer versus silicon with some organic passivation. In some embodiments, silicon oxide is deposited selectively on metal or metal alloy or metal oxide versus dielectric films with organic passivation. In some embodiments, passivation is present as a passivation layer.

Examples of organic materials according to the current disclosure include but are not limited to polyimide, polyamide, poly(methyl methacrylate) (PMMA). Additional examples of organic materials are polyurea, polyurethanes, polythioureas, polyesters, polyimines, polyamic acid and other polymeric forms or mixtures of the above materials. In some embodiments, the organic material may comprise, consist essentially of, or consist of a precursor material to a polymer film that can be converted or polymerized by a treatment process. For example, the as deposited organic material may comprise a polyimide or polyamide. In some embodiments, the deposited organic material may comprise, consist essentially of, or consist of polyimide films resulting from incomplete reaction. In some embodiments, the deposited organic film may comprise, consist essentially of, or consist of polyimide containing some polyamic acid. In some embodiments, polyamic acid is converted to a polyimide. Conversion processes known in the art include annealing, plasma (e.g., using an inert gas), chemical treatment (e.g., using an anhydride), UV treatment, and other post-deposition treatments.

In some embodiments of the current disclosure, the second material may comprise, consist essentially of, or consist of a passivation agent. In other, words, the second portion may comprise a passivation agent. A passivation agent is substance, compound or a mixture of compounds that may inhibit the deposition or growth of a depositable material on a substrate. Various passivation agents are known in the art. Some passivation agents comprise organic materials. In some embodiments, the passivation agent is an organic material according to the current disclosure. In other words, organic material may function as an organic passivation agent.

In the method according to the current disclosure, silicon oxide is selectively deposited on the first portion relative to the second portion. Selectivity can be described as a percentage calculated as [(deposition on first surface)−(deposition on second surface)]/(deposition on the first surface). Deposition can be measured in different ways. In some embodiments, deposition may be given as the measured thickness of the deposited material. In some embodiments, deposition may be given as the measured amount of material deposited.

Is some embodiments, selectivity is greater than about 10%, greater than about 35% or greater than about 50%. In some embodiments, selectivity is greater than about 75%, greater than about 85%, greater than about 90% or greater than about 93%. In some embodiments, selectivity is greater than about 95%, greater than about 98% greater than about 99% or greater than about 99.5%. In some embodiments described herein, selectivity can change over the duration of or thickness of a deposition.

In some embodiments, the deposition of silicon oxide only occurs on the first portion and does not occur on the second portion. In some embodiments, the deposition on the first portion relative to the second portion is at least about 80% selective, being selective enough for some applications. In some embodiments, the deposition on the first portion relative to the second portion is at least about 50% selective, which may be selective enough for some applications. In some embodiments, the deposition on the first portion relative to the second portion is at least about 10% selective, which may be selective enough for some applications.

In some embodiments, the passivation agent, which may be an organic passivation agent, is selectively deposited on the second portion relative to the first portion before providing the silicon precursor in the reaction chamber. In some embodiments, the passivation agent, which may be an organic passivation agent, is selectively deposited on the second portion relative to the first portion before providing the reactant in the reaction chamber.

In some embodiments, the method further comprises selectively removing the passivation agent, which may be an organic passivation agent, after depositing silicon oxide on the first portion. The removal of the passivation agent may lead to the removal of some silicon oxide from the first portion. The method according to the current disclosure may comprise more than one deposition of a passivation agent. Depositing passivation agent a second and/or a further time may be beneficial, for example, in situations where the selectivity is less than 100%. In such embodiments, there may be some deposition of silicon oxide on the second portion comprising a passivation agent. The intermittent removal of passivation agent and its re-deposition may improve the selectivity by removing the silicon oxide deposited in unwanted areas of the substrate. The removal of passivating agent may be optional. Simply depositing more of the passivation agent may be sufficient.

In some embodiments of the current method, one or more unit deposition cycles are performed. A unit deposition cycle comprises providing the silicon precursor in the reaction chamber and providing the reactant in the reaction chamber. The unit deposition cycle may comprise additional phases, such as purging or deposition of a passivation agent.

In some embodiments, metal oxide and/or metal silicate may be deposited. Metal oxide or metal silicate-containing material according to the current disclosure may find use as, for example, UV underlayers, adhesion layers, in patterning, or as sacrificial layers for various purposes. The metal oxide and/or metal silicate-containing material may form layers. In some embodiments, the metal oxide is aluminum oxide (such as Al₂O₃), titanium oxide (such as TiO₂), tantalum oxide (such as Ta₂O₅), niobium oxide (such as NbO₂, Nb₂O₅), tungsten oxide (such as Al₂O₃, WO₂, W₂O₅), hafnium oxide (such as HfO₂) or zirconium oxide (such as ZrO₂). The metal oxide and/or metal silicate-containing material may be deposited selectively as described above. In embodiments where silicon oxide or silicon oxide-containing layer comprises a metal oxide and/or metal silicate, the silicon oxide content of the layer may be lowered compared to layers that do not comprise a metal oxide and/or metal silicate.

In some embodiments, metal precursors may be selected from alkyl amides, amidinate, alkoxide, alkyl, halide, cyclopentadiene and β-diketonate compounds. In some embodiments, metal precursor may be tetrakis (dimethylamido)titanium, titanium(IV)isopropoxide, dimethyl aluminum isopropoxide, trimethyl aluminum (TMA), diethyl zinc, Tetrakis(ethylmethylamido)hafnium(IV), Tetrakis(ethylmethylamido)zirconium(IV), and Tetrakis(dimethylamido)hafnium(IV), Dimethylbis(cyclopentadienyl)hafnium(IV) etc. In some embodiments, alkyl amide metal precursors are chosen for metals such as titanium, gallium, germanium, and tantalum. In some embodiments, the method comprises providing a metal precursor in the reaction chamber. In some embodiments, the silicon precursor, the reactant and the metal precursor are provided in the reaction chamber alternately and sequentially. Depending on the desired metal oxide content of silicon oxide, the ratio between providing metal precursor into the reaction chamber and providing silicon precursor into the reaction chamber may be adjusted. For example, the ratio between providing metal precursor into the reaction chamber and providing silicon precursor into the reaction chamber may be, for example, 1:1, 1:2, 1:5, 1:8, 1:10, 1:15, 1:20; 1:30, 1:50, 1:100, 2:1 or 5:1 or 10:1 or 20:1.

In some embodiments, the silicon precursor according to the current disclosures comprises triacetoxy vinyl silane (CAS nr 4130-08-9), and the reactant comprises TMA. In such embodiments, the deposition temperature may be, for example from about 200° C. to about 450° C., such as 250° C., 300° C. or 350° C. The amount of silicon in the deposited aluminum silicate-containing material may be, for example from about 2 to about 20 at. %, such as 5 at. %, 10 at. % or 15 at. %. The amount of carbon in the deposited aluminum silicate-containing material may be, for example from about 0.5 to about 15 at. %, such as 1 at. %, 3 at. % or 8 at. %.

In another embodiment, a three-step vapor deposition process, such as an ALD process, may be used to deposit material with tunable composition. A silicon precursor and a reactant according to the current disclosure maybe combined with an organometallic precursors to deposit metal silicate material. For example, a deposition cycle may comprise providing a silicon precursor (such as silicon tetraacetate), metal precursor (such as TMA) and a reactant (such as water) into the reaction chamber sequentially. In an embodiment, each deposition cycle comprises two subcycles, one for metal oxide, and one for silicon oxide. For example, metal precursor (such as TMA) and a reactant (such as water) may be provided into the reaction chamber alternately and sequentially for a predetermined number of times, after which silicon precursor (such as silicon tetraacetate) and reactant (such as water) are provided into the reaction chamber for a predetermined number of times. The number of times each subcycle is repeated may be selected independently. For example, each subcycle may be performed from about 5 to about 50 times, such as 10, 20 or 30 times. Adjusting the relative amounts of the subcycles, material of desired composition may be obtained. In some embodiments, the deposited material comprises from 5 to 50 at. % silicon. In some embodiments, the deposited material comprises from 2 to 20 at. % carbon. In some embodiments, the deposited material comprises from 10 to 40 at. % aluminum. In some embodiments, the deposited material comprises from 45 to 65 at. % oxygen. However, the amount of each element in the deposited material depends on the selected cycling regime and deposition conditions.

In some embodiments, a metal alkoxide may be used to increase the rate of depositing a silicon oxide-containing material. A metal alkoxide treatment may be used in combination with the three-step process described above. In some embodiments, a metal alkoxide, such as dimethyl aluminum isopropoxide is used intermittently for improving deposition rate. For example, a metal alkoxide reactant may be provided into a reaction chamber in a single pulse, without providing additional reactants. Thereafter, a silicon precursor and a reactant may be provided in a subcycle that is repeated a predetermined number of times before a metal alkoxide reactant is provided again. Without limiting the current disclosure to any specific theory, a metal alkoxide may improve the availability of hydroxyl groups on substrate surface to enhance the chemisorption of the silicon precursor to the substrate. In some embodiments, the metal alkoxide reactant, such as dimethyl aluminum isopropoxide, is provided into the reaction chamber (i.e., pulsed) for 1 to 20 seconds, such as 2 seconds, 3 seconds, 5 seconds or 10 seconds. In some embodiments, a subcycle comprising providing a silicon precursor and a reactant into the reaction chamber is performed from 1 to 50 times, such as 5, 6, 8, 10, 15 or 20 times before a metal alkoxide reactant (comprising, for example, dimethyl aluminum isopropoxide) is provided into the reaction chamber again.

Metal alkoxide pulsing may leave some metal behind in the deposited material. In embodiments comprising using dimethyl aluminum isopropoxide, the deposited material may contain aluminum. In some embodiments, silicon oxide-containing material comprises from about 1 at. % to about 10 at. % aluminum. Silicon content of such materials may be from about 20 at. % to about 40 at. %, for example, about 25 at. %, about 30 at. % or about 35 at. %. However, the amount of each element in the deposited material depends on the selected cycling regime and deposition conditions.

The use of a metal alkoxide may shorten the reactant pulsing time to achieve a given material deposition speed. In an embodiment in which dimethyl aluminum isopropoxide is used as a metal alkoxide such that after each dimethyl aluminum isopropoxide pulse, silicon precursor (silicon tetraacetate) and a reactant (water) are pulsed between three and nine times, the deposition speed per each silicon pulse is at least doubled, despite the deposition temperature being 20° C. lower, and the duration of the reactant pulse being less than 10% compared to the process without the metal alkoxide pulse. Thus, it may be possible to lower the deposition temperature when using a metal alkoxide reactant. In some embodiments, the deposition temperature may be from about 50° C. to about 200° C., such as about 60° C., or about 80° C. or about 100° C. The selectivity of the deposition process may be improved, such that nucleation on a passivation layer is reduced when a metal alkoxide reactant is used.

In another aspect, a deposition assembly for depositing silicon oxide on a substrate is disclosed. The deposition assembly comprises a reaction chamber constructed and arranged to hold the substrate; and a precursor injector system constructed and arranged to provide a precursor and/or a reactant into the reaction chamber. The deposition assembly comprises a precursor vessel constructed and arranged to contain and evaporate a silicon precursor comprising a silicon atom connected to at least one oxygen atom, the at least one oxygen atom being connected to a carbon atom. The assembly is constructed and arranged to provide the silicon precursor via the precursor injector system to the reaction chamber to deposit silicon oxide on the substrate.

In some embodiments of the deposition assembly, the vessel comprises a vaporizer constructed and arranged to evaporate the silicon precursor. In certain embodiments, the vaporizer is constructed and arranged to vaporize the silicon precursor at a temperature of 65° C. to 250° C. In some embodiments, the vaporizer according to the current disclosure is a vaporizer in which the surface of the vaporizer does not come in direct contact with thermal heaters. Such a vaporizer may allow improved uniformity in heating in embodiments where radiation based heating is used. In some embodiments, the vaporizer may be a suspended vaporizer. In such a vaporizer there is no direct thermal contact, for example between two metal surfaces.

In some embodiments, an isolated jacket may be placed around the vessel to stabilize the vessel temperature. This may reduce surface temperature fluctuation. In some embodiments, an inner surface of the vaporizer may be material other than metal. At least one of inner surfaces of the vaporizer may comprise a polymer coating or a high performance thermoplastic (HTP).

In some embodiments, the deposition apparatus comprises a pump constructed and arranged to pump down the pressure in the reaction chamber to below 50 Torr. In some embodiments, the deposition apparatus comprises a heater constructed and arranged to control the temperature in the reaction chamber between 65° C. and 500° C.

### DETAILED DESCRIPTION OF THE DRAWINGS

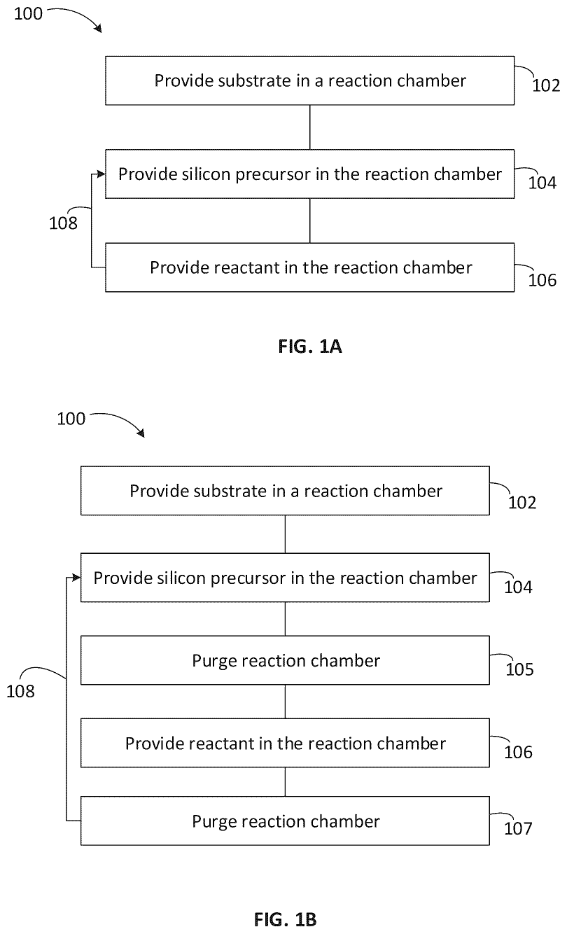

FIG. 1A illustrates a method 100 of depositing silicon oxide in accordance with at least one embodiment of the disclosure. Method 100 includes providing a substrate within a reaction chamber (102), providing silicon precursor according to the current disclosure in the reaction chamber (104) and providing reactant comprising hydrogen atoms in the reaction chamber (106).

During step 102, a substrate is provided into a reaction chamber of a reactor. The reaction chamber can form part of an atomic layer deposition (ALD) reactor. The reactor may be a single wafer reactor. Alternatively, the reactor may be a batch reactor. Various phases of method 100 can be performed within a single reaction chamber or they can be performed in multiple reactor chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, a reactor including the reaction chamber can be provided with a heater to activate the reactions by elevating the temperature of one or more of the substrate and/or the reactants and/or precursors.

During step 102, the substrate can be brought to a desired temperature and pressure for providing silicon precursor in the reaction chamber 104 and/or providing reactant in the reaction chamber 106. A temperature (e.g., of a substrate or a substrate support) within a reaction chamber can be, for example, from about 100° C. to about 450° C., or from about 150° C. to about 400° C. As a further example, a temperature within a reaction chamber can be from about 200° C. to about 400° C., or from about 300° C. to about 350° C. Exemplary temperatures within the reaction chamber are 75° C., 125° C., 175° C., 225° C., 275° C., 325° C. and 375° C.

A pressure within the reaction chamber can be about 0.001 Torr, or less than 0.01 Torr, less than 0.1 Torr, less than 10 Torr or less than 50 Torr.

Silicon precursor is provided in the reaction chamber (104) containing the substrate. Without limiting the current disclosure to any specific theory, silicon precursor may chemisorb on the substrate during providing silicon precursor in the reaction chamber (104). The duration of providing silicon precursor in the reaction chamber (silicon precursor pulse time) may be, for example 0.5 s, 1 s, 1.5 s, 2 s, 2.5 s, 3 s, 3.5 s, 4 s, 4.5 s or 5 s. In some embodiments, the duration of providing silicon precursor in the reaction chamber (silicon precursor pulse time) is may be more than 5 s or more than 10 s or about 20 s.

When reactant is provided in the reaction chamber (106), it may react with the chemisorbed silicon precursor, or its derivate species, to form silicon oxide. The duration of providing reactant in the reaction chamber (reactant pulse time) may be, for example 0.5 s, 1 s, 1.5 s, 2 s, 2.5 s, 3 s, 3.5 s, 4 s, 4.5 s, 5 s, 6 s, 7 s, 8 s, 9 s, 10 s, 11 s or 12 s. In some embodiments, the duration of providing reactant in the reaction chamber is be more than 15 s or more than 20 s or about 30 s. Without limiting the current disclosure to any specific theory, the reactant pulse may be shorter than the silicon precursor pulse.

Stages 104 and 106, performed in any order, may form a deposition cycle, resulting in the deposition of silicon oxide. In some embodiments, the two stages of silicon oxide deposition, namely providing the silicon precursor and the reactant in the reaction chamber (104 and 106), may be repeated (loop 108). Such embodiments contain several deposition cycles. The thickness of the deposited silicon oxide may be regulating by adjusting the number of deposition cycles. The deposition cycle (loop 108) may be repeated until a desired silicon oxide thickness is achieved. For example 50, 100, 150, 200, 250, 300, 400, 500, 600, 700, 800 or 900 deposition cycles may be performed.

The amount of silicon oxide deposited during one cycle (growth per cycle) varies depending on the process conditions, and may be, for example 0.03 Å/cycle, 0.05 Å/cycle, 0.1 Å/cycle, 0.15 Å/cycle, 0.2 Å/cycle, 0.25 Å/cycle or 0.3 Å/cycle, 1 Å/cycle, 3 Å/cycle or 5 Å/cycle. Depending on the deposition conditions, deposition cycle numbers etc., silicon oxide or silicon oxide-containing layers of variable thickness may be deposited. For example, silicon oxide or silicon oxide-containing layer may have a thickness between approximately 0.3 nm and 30 nm, such as approximately 0.5 nm, 1 nm, 1.5 nm, 2 nm, 2.5 nm, 3 nm, 3.5 nm, 4 nm, 4.5 nm, 5 nm, 6 nm, 7 nm, 8 nm, 10 nm, 15 nm, 20 nm or 25 nm. The desired thickness may be selected according to the application in question.

Silicon precursor and reactant may be provided in the reaction chamber in separate steps (104 and 106). FIG. 1B illustrates an embodiment according to the current disclosure, where steps 104 and 106 are separate by purge steps 105 and 107. In such embodiments, a deposition cycle comprises one or more purge steps (103, 105). During purge steps, precursors and/or reactants can be temporally separated from each other by inert gases, such as argon (Ar), nitrogen (N₂) or helium (He) and/or a vacuum pressure.

Purging the reaction chamber (103, 105) may prevent or mitigate gas-phase reactions between a silicon precursor and a reactant, and enable self-saturating surface reactions. Surplus chemicals and reaction byproducts, if any, are removed from the substrate surface, such as by purging the reaction chamber or by moving the substrate, before the substrate is contacted with the next reactive chemical. In some embodiments, however, the substrate may be moved to separately contact a silicon precursor and a reactant. Because the reactions can self-saturate, strict temperature control of the substrates and precise dosage control of the precursors may not be required. However, the substrate temperature is preferably such that an incident gas species does not condense into monolayers or multimonolayers nor thermally decompose on the surface.

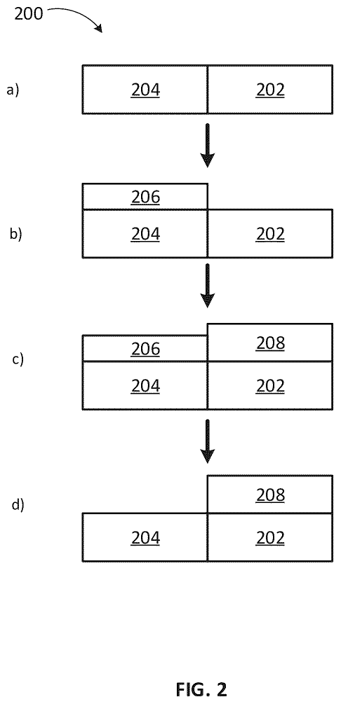

FIG. 2 is a schematic representation of a selective embodiment of the current disclosure. As noted above, the substrate provided during step 102 may include a surface comprising a first portion and a second portion. In the exemplary embodiment of FIG. 2, a substrate 200 comprising a surface having a first portion 202 and a second portion 204 is depicted. The substrate 200 may comprise additional layers below the surface. In panel a), the surface of the substrate is formed by the first portion 202 and second portion 204. The first portion 202 comprises, consist essentially of, or consist of first material. The second portion 204 comprises, consist essentially of, or consist of second material. First material and second material are different materials. Each of the first and second material may be SiO₂, SiN, SiOC, SION, SiOCN or low k material, for example. The first and second material may be a metal-containing silicon oxide, a metal nitride, a metal boride or a metal carbide, a metal or a metal alloy or a metal oxide. In the illustration of FIG. 2, the first portion 202 and the second portion 204 are on the same vertical level. However, in reality the first and second portions 202, 204 could be on different levels.

In panel b) of FIG. 2, the second portion 204 comprises a passivation agent 206. The passivation agent 206 may comprise an organic material. The passivation agent 206 may be an organic passivation agent. In panel b) the surface of the substrate is formed by the first portion 202 and the second portion 204 covered by the passivation agent 206.

In panel c) of FIG. 2, silicon oxide 208 according to the current disclosure has been selectively deposited on the first portion 202. The deposition of silicon oxide 208 may be done in one or more deposition cycles. The relative thickness of the passivation agent and the silicon oxide layer can be different than what is depicted in the figure. In the exemplary embodiment of FIG. 2, the passivation agent 206 is deposited on the substrate before silicon oxide 208 is deposited on the substrate 200. Although not depicted in the schematic representation of FIG. 2, in some embodiments, there may be some deposition of silicon oxide 208 on the passivation agent 206. However, in most embodiments, the growth of silicon oxide 208 on the passivation agent 206 is significantly slower than on the first portion 202.

Panel d) of FIG. 2 shows the substrate 200 after passivation agent 206 has been removed from the second portion 204. In embodiments where silicon oxide would be deposited on the passivation agent 206 to some extent, the removal of the passivation agent 206 would also remove any silicon oxide deposited on it. After the removal of the passivation agent 206, the second portion 204 is forming the surface of the substrate 200 without the passivation agent 206 together with the silicon oxide 208 deposited on the first surface 202. The method depicted in FIG. 2 may be followed by further deposition methods and/or treatments. Further, although not depicted in FIG. 2, passivation and deposition of silicon oxide may be repeated.

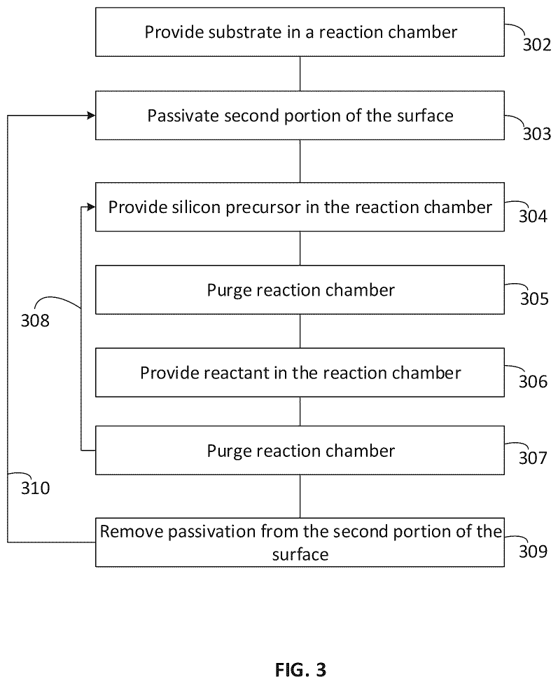

FIG. 3 is an illustration of a method of depositing silicon oxide 300 in which the second portion of the substrate may be repeatedly passivated by a passivation agent. First, a substrate is provided in the reaction chamber 302. The substrate comprises a first portion and a second portion as described above. In the embodiment of FIG. 3 second surface of the substrate is passivated by a passivation agent 303. The passivation agent may be deposited on the surface. In some other embodiments, the passivation agent is introduced on the surface at a stage before providing the substrate in the reaction chamber 302. In other words, the substrate may be passivated in another reaction chamber of a cluster tool. The passivation may also take place in another tool.

In some embodiments, the passivation agent is an organic passivation agent. However, any suitable passivation agents or passivation methods known in the art may be used. The selection of the passivation method may depend on the properties of the first and second portions, as is evident for those skilled in the art. After the second surface has been passivated 303, silicon oxide is selectively deposited on the first surface 304-307. The deposition of silicon oxide may comprise providing a silicon precursor and a reactant alternately and sequentially into the reaction chamber (304, 306) as described above. The reaction chamber may be purged 305, 307 after providing silicon precursor and/or after providing reactant in the reaction chamber. The deposition cycle may be repeated (loop 308) until desired thickness and/or layer coverage of silicon oxide has been achieved.

After one or more silicon oxide deposition cycles, passivation agent may be removed from the second portion of the substrate surface 309. In some embodiments, the silicon oxide deposition is complete before the passivation agent is removed from the second portion 309. In some embodiments, separate passivation agent removal 309 is unnecessary, and substrate processing may continue without it. In some embodiments, the removal of the passivation agent 309 may be done before the silicon oxide deposition is complete. In such embodiments, the second portion of the substrate surface may be passivated again (loop 310). The frequency of passivation agent removal varies according to process specifics and can be determined by the skilled person. However, in certain embodiments, the constitution of the second and first surface may allow the continuation of silicon oxide deposition without repeating passivation.

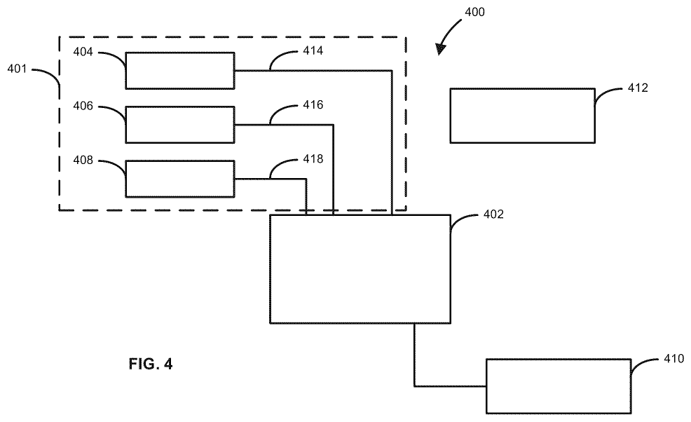

FIG. 4 is a schematically presented exemplary embodiment of a deposition assembly 400 for depositing silicon oxide on a substrate. The deposition assembly 400 can be used to perform a method according to the current disclosure and/or form a structure or device portion according to the current disclosure. In the illustrated example, deposition assembly 400 includes one or more reaction chambers 402 constructed and arranged to hold the substrate, and a precursor injector system 401 constructed and arranged to provide a precursor and/or a reactant into the reaction chamber 402. The reaction chamber 402 can comprise any suitable reaction chamber, such as an ALD or CVD reaction chamber. The deposition assembly 400 may comprise a heater constructed and arranged to control the temperature in the reaction chamber between 65° C. and 500° C.

The deposition assembly further includes a precursor vessel 404 constructed and arranged to contain and evaporate a silicon precursor comprising a silicon atom connected to at least one oxygen atom, the at least one oxygen atom being connected to a carbon atom. The deposition assembly 400 is constructed and arranged to provide the precursor via the precursor injector system 401 to the reaction chamber 402 to deposit the silicon oxide on the substrate according to the current disclosure.

The precursor injector system 401 of the deposition assembly 400 further comprises a reactant source 406, an optional purge gas source 408, an exhaust source 410, and a controller 412. The silicon precursor source 404 can include a vessel and one or more silicon precursors as described in the current disclosure-alone or mixed with one or more carrier (e.g., inert) gases. Reactant source 406 can include a vessel and one or more reactants according to the current disclosure-alone or mixed with one or more carrier gases. One or both vessels may comprise a vaporizer constructed and arranged to evaporate silicon precursor or reactant, respectively, according to the current disclosure. The vaporizers may be constructed and arranged to vaporize the silicon precursor or the reactant, respectively, at a suitable temperature. The suitable temperature for the silicon precursor may be, for example, 60° C. to 500° C. Purge gas source 408 can include one or more inert gases as described herein. Although illustrated with three gas sources 404-408, deposition assembly 400 can include any suitable number of gas sources. Gas sources 404-408 can be coupled to reaction chamber 402 via lines 414-418, which can each include flow controllers, valves, heaters, and the like. The deposition apparatus 400 may contain a pump constructed and arranged to pump down the pressure in the reaction chamber to below 50 Torr. The pump may be comprised in the exhaust source 410. The exhaust source 410 may comprise one or more vacuum pumps.

Controller 412 includes electronic circuitry and software to operate valves, manifolds, heaters, pumps and other components included in the deposition assembly 400. Such circuitry and components operate to introduce one or more precursors, reactants, and purge gases from the respective sources 404-408. Controller 412 can control timing of gas pulse sequences, temperature of the substrate and/or reaction chamber, pressure within the reaction chamber, and various other operations to provide proper operation of the deposition assembly 400. Controller 412 can include control software to electrically or pneumatically control valves to control flow of precursors, reactants and purge gases into and out of the reaction chamber 402. Controller 412 can include modules such as a software or hardware component, which performs certain tasks. A module can advantageously be configured to reside on the addressable storage medium of the control system and be configured to execute one or more processes.

Other configurations of deposition assembly 400 are possible, including different numbers and kinds of precursor and reactant sources and purge gas sources. Further, it will be appreciated that there are many arrangements of valves, conduits, precursor sources, and purge gas sources that may be used to accomplish the goal of appropriately feeding gases into reaction chamber 402. Further, as a schematic representation of an assembly, many components have been omitted for simplicity of illustration, and such components may include, for example, various valves, manifolds, purifiers, heaters, containers, vents, and/or bypasses, as well as safety features.

During operation of deposition assembly 400, substrates, such as semiconductor wafers (not illustrated), are transferred from, e.g., a substrate handling system to reaction chamber 402. Once substrate(s) are transferred to reaction chamber 402, one or more gases from gas sources 404-408, such as precursors, reactants, carrier gases, and/or purge gases, are introduced into reaction chamber 402.

1. A method for depositing an oxide on a substrate, the method comprising:
providing a substrate, having a first portion and a second portion, in a reaction chamber;
providing a silicon precursor in the reaction chamber, the silicon precursor comprising a silicon atom connected to at least one oxygen atom, the at least one oxygen atom being connected to a carbon atom and;
providing a reactant in the reaction chamber to selectively form silicon oxide on the first portion relative to the second portion.

2. The method according to claim 1, wherein the silicon precursor comprises a compound according to formula I,
SiRₐ(OOCR′)₄₋ₐ, Formula I
wherein, each R and R′ are independently selected from hydrogen or unsubstituted, substituted, saturated, unsaturated and/or functionalized hydrocarbons, and 4>a≥0.

3. The method according to claim 1, wherein the silicon precursor is selected from a group consisting of silicon tetraacetate (triacetyloxysilyl acetate), triacetoxy vinyl silane, silicontetrapropionate, triacetoxysilane, triacetoxy(methyl)silane, triacetoxy(methoxy)silane, diacetoxydimethylsilane.

4. The method according to claim 1, wherein the reactant comprises at least one atom not being hydrogen.

5. The method according to claim 1, wherein the reactant does not comprise oxygen.

6. The method according to claim 1, wherein the reactant comprises ammonia (NH₃) or ammonia nitrogen (NH₃—N₂) or ammonia-hydrogen (NH₃—H₂) mixture.

7. The method according to claim 1, wherein the reactant comprises an amine.

8. The method according to claim 1, wherein the reactant consists essentially of two or more of the elements selected from oxygen, nitrogen and hydrogen.

9. The method according to claim 1, wherein the silicon precursor comprises at least one other oxygen atom connected to the carbon atom.

10. The method according to claim 1, wherein the method is a cyclic deposition method.

11. The method according to claim 1, wherein the method is a thermal deposition method.

12. The method according to claim 1, wherein the reactant consists essentially of oxygen and nitrogen.

13. The method according to claim 1, wherein the method comprises providing a metal alkoxide reactant into the reaction chamber to form a metal silicate.

14. The method according to claim 13, wherein the metal alkoxide is dimethyl aluminum isopropoxide.

15. The method according to claim 13, wherein the method is a cyclic deposition method, and the silicon precursor and the reactant are provided into the reaction chamber at least twice for each time the metal alkoxide is provided into the reaction chamber.

16. The method according to claim 1, wherein the first portion comprises a first material and the second portion comprises a second material different than the first material.

17. The method according to claim 16, wherein the first material comprises a dielectric material.

18. The method according to claim 16, wherein the first material comprises a metal or a metal oxide.

19. The method according to claim 16, wherein the first material comprises a metal nitride or a metal carbide or a metal boride.

20. The method according to claim 16, wherein the second material comprises a passivation agent, and wherein the method comprises repeating steps of depositing and removing the passivation agent.
